(19) United States
(12) Patent Application Publication
(10) Pub. No.: US 2004/0021155 A1
(43) Pub. Date: Feb. 5, 2004

(54) Solid-state image sensing device

(76) Inventor: Kouichi Harada, Kanagawa (JP)

Correspondence Address: ROBERT J. DEPKE LEWIS T. STEADMAN, HOLLAND & KNIGHT LLC, 131 SOUTH DEARBORN, 30TH FLOOR, CHICAGO, IL, 60603, US

(21) Appl. No.: 10/375,674

(22) Filed: Feb. 26, 2003

(30) Foreign Application Priority Data
Mar. 1, 2002 (JP) JP2002-055358

(51) Int. Cl. H01L 27/148; H01L 31/00

(52) U.S. Cl. 257/222; 257/233; 257/443; 257/461

(57) ABSTRACT

An interline transmission-format solid-state image-sensing device, which reads out all pixels, includes a two-dimensional array of a plurality of photosensitive units and a plurality of vertical CCD segments. Each vertical CCD segment is provided for one vertical line of the photosensitive units. A plurality of vertical transmission electrodes extends above each of these vertical transmission electrodes. At least one of these vertical transmission electrodes is arranged above the photosensitive units and is composed of a transparent film at least in regions above the photosensitive units. This electrode structure is suitable for high-rate signal transmission,

### BACKGROUND OF THE INVENTION

1. Field of the Invention

The present invention relates to an interline-transmission (IT)-format solid-state image-sensing device.

2. Description of the Related Art

CCD solid-state image-sensing devices are widely used as image input terminals in digital still cameras (DSCs), digital video cameras (DVCs), PC cameras, and cameras for PDA terminals. CCD solid-state image-sensing devices are categorized into FF (full-frame)-CCDs, FT (frame transmission)-CCDs, IT (interline transmission)-CCDs, and IT (frame interline transmission)-CCDs.

An IT-CCD area sensor has many photocells (photosensitive units) arranged in a two-dimensional array in which a plurality of vertical transmission CCDs (V registers) are arranged between the photocells lying in each vertical lines, and horizontal transmission CCDs are disposed in one line that adjacent to the vertical transmission CCDs in the last line. In the IT-CCD area sensor, vertical transmission CCDs are driven in a two-phase, three-phase, or four-phase drive mode, and accumulation modes are categorized into a field accumulation mode and a frame accumulation mode.

For example, in a general camera, the IT-CCD area sensor is used in a field accumulation mode that mixes signal charges of adjoining vertical two lines in a vertical CCD in synchronization with 2:1 interlace scanning of broadcast systems such as NTS and PAL. This field accumulation mode has an advantage of high dynamic resolution and also has a disadvantage of a poor vertical resolution (240 TV lines) in a still image.

In contrast, a frame accumulation mode in which each pixel is read out without mixing has a high vertical resolution of 480 TV lines. However, this mode disadvantageously requires a photoflash and a mechanical shutter for image pickup of an object that moves at a high speed.

High resolution in recent digital still cameras have been achieved by increasing the number of pixels (unit cells) in the horizontal direction to satisfy the requests for further compactness and higher resolution in the cameras. Unfortunately, this method has a limited maximum vertical resolution of about 350 TV lines as long as signals of adjoining two lines are mixed.

In order to solve such a problem, a progressive scan CCD (PS-CCD) image sensor is proposed. The PS-CCD image sensor is a non-interlace IT-CCD image sensor that independently reads out signal charges of all pixels for each field to strike a balance between high dynamic resolution and high vertical resolution. For example, a vertical transmission unit with three-layer electrodes and three-phase drive is disclosed in Technical Report of The Institute of Television Engineers—Information Input and Display; pp.8-12, November 1994, entitled “½-inch, 330,000-pixels, square-grid progressive scan CCD image sensing device”.

Also, a vertical transmission unit with three-layer electrodes and four-phase drive is disclosed in Preprint of 1995 Annual Meeting of The institute of Television Engineers; pp.93-94, entitled “⅓-inch, 330,000-pixels, square-grid progressive scan CCD image sensing device”.

In conventional IT-CCDs including the PS-CCDs disclosed in these documents, all vertical transmission electrodes are formed of polycrystalline silicon (poly-Si) and are completely or partially overlaid to each other between adjacent photocells.

Thus, these electrodes have a large overlap area and thus have a large coupling capacitance. As a result, the vertical transmission CCD segment consumes a large amount of power.

Furthermore, the overlying electrode structure inevitably has a large step (a high bank of the electrodes). Such a large step causes a large aspect ratio (a large ratio of the vertical size to the horizontal size) of the unit cell. For a lens of a reduced F value (focal distance), a large aspect ratio precludes an increase in sensitivity. Thus, the size of the unit cells cannot be further reduced.

### SUMMARY OF THE INVENTION

An object of the present invention is to provide a solid-state image-sensing device that consumes a reduced amount of electric power in a vertical transmission CCD segment.

Another object of the present invention is to provide a solid-state image-sensing device having unit cells with a reduced size.

In an interline transmission-format solid-state image-sensing device according to the present invention, at least one of a plurality of vertical transmission electrodes is arranged above photosensitive units and is composed of a transparent film at least in regions above the photosensitive units. The transparent vertical transmission electrodes may be composed of a transparent conductive thin film of an In₂O₃-based material such as ITO or a ZnO-based material, a polycrystalline silicon thin film that can transmit light, or a composite film thereof.

When at least two of these vertical transmission electrodes are composed of the transparent film, these are arranged with a predetermined gap (for insulation) in the same plane. That is, the solid-state image-sensing device has a single-layer electrode structure.

Preferably, the vertical transmission electrodes have windows above parts of the photosensitive units so that light is directly incident above the photosensitive units. Preferably, the thickness of the vertical transmission electrodes is smaller above the photosensitive units than above the vertical CCD units. Alternatively, the thickness of the vertical transmission electrodes above each of the photosensitive units may be smaller in regions vertically extending near vertical edges of the photosensitive unit than in other portions. Alternatively, the thickness of the vertical transmission electrodes above each of the photosensitive units is smaller in regions near edges of the photosensitive unit than in other portions.

In the interline transmission-format solid-state image-sensing device of the present invention, the substantially entire regions other than the photosensitive units are preferably shaded from light. More specifically, the solid-state image-sensing device preferably further comprises a shading film over the vertical transmission electrodes, the shading film having windows above the photosensitive units so that light is directly incident on the photosensitive units. The shading film has projections that vertically extend at vertical edges of each of the photosensitive units. Alternatively, the shading film may have projections at edges of each of the photosensitive units.

Since the vertical transmission electrodes have a single-layer structure above the photosensitive units in the solid-state image-sensing device of the present invention, high transmittance of light is achieved above the photosensitive units, and the coupling capacitance between the vertical transmission electrodes is reduced. Furthermore, the single-layer structure can reduce the steps (difference in height) between the electrodes.

### BRIEF DESCRIPTION OF THE DRAWINGS

FIG. 1 is a schematic diagram of a solid-state image-sensing device according to an embodiment of the present invention;

FIG. 2(A) is a plan view of a unit cell of the solid-state image-sensing device shown in FIG. 1; FIG. 2(B) is a schematic view showing a planar shape of vertical transmission electrodes; FIG. 2(C) is a cross-sectional view taken along line A-A′ in FIG. 2(A);

FIG. 3(A) is a cross-sectional view of a vertical transmission electrode of a solid-state image-sensing device according to a second embodiment; FIGS. 3(B1) to 3(B5) are cross-sectional views showing multilayer structures of the vertical transmission electrode shown in FIG. 3(A);

FIG. 4(A) is a cross-sectional view of a vertical transmission electrode of a solid-state image-sensing device according to a third embodiment; FIGS. 4(B1) and 4(B2) are cross-sectional views showing multilayer structures of the vertical transmission electrode shown in FIG. 3(A);

FIGS. 5(A) and 5(B) are plan views of unit cells in which vertical transmission electrodes of a solid-state image-sensing device are partially thinned in predetermined regions;

FIG. 6(A) is a plan view of a unit cell according to another embodiment of the solid-state image-sensing device shown in FIG. 1; and FIG. 6(B) is a schematic view showing a planar shape of vertical transmission electrodes of the unit cell.

### DESCRIPTION OF THE PREFERRED EMBODIMENTS

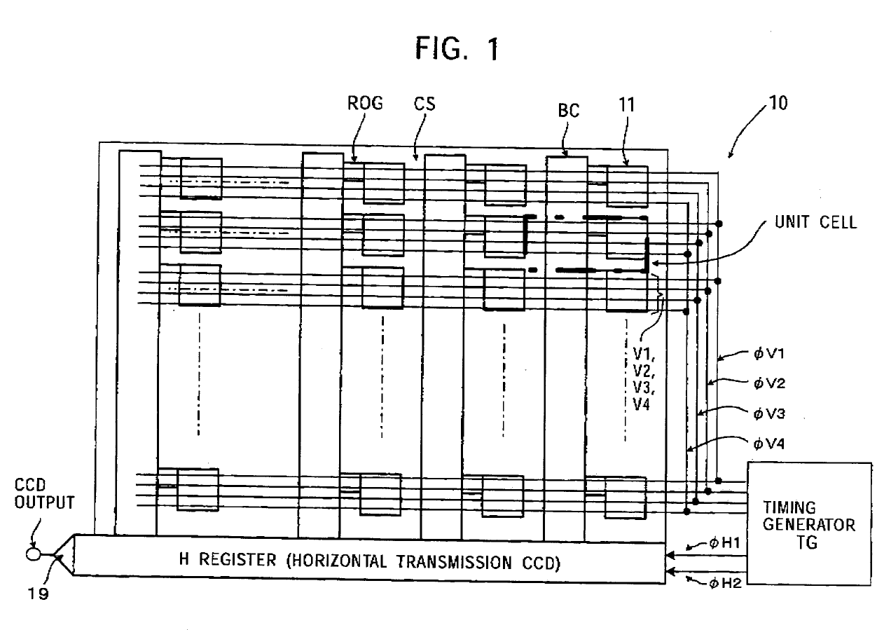

The preferred embodiments of the present invention will now be described with reference to the drawing. FIG. 1 is a schematic view of a solid-state image-sensing device 10 according to an embodiment of the present invention. The solid-state image-sensing device 10 includes many photosensitive units (photocells) 11 composed of photodiodes corresponding to pixels. The photosensitive units 11 are arranged in a two-dimensional array (columns or vertical lines and rows or horizontal lines) and constitute an image-sensing unit. The photosensitive units 11 accumulate signal charges that are generated in proportion to the intensity of the incident light.

The solid-state image-sensing device 10 has a V register (a vertical CCD or a vertical transmission segment) BC including four vertical transmission electrodes V1 to v4 for every vertical line of the photosensitive units 11 (for every unit cell) in this embodiment, the number of the vertical transmission electrodes corresponding to four-phase drive. The vertical transmission electrodes V1 to V4 are formed of a transparent electrode material and extend in the horizontal direction above the corresponding photosensitive unit 11.

In this embodiment, these electrodes are transparent over the entire region. Alternatively, these electrodes may be transparent at least above the corresponding photosensitive unit 11.

The repeating unit in the transmission direction of the vertical transmission electrodes V1 to V4 is defined for each pixel (unit cell) of the photosensitive unit 11. The transmission direction is vertical in FIG. 1 and the V registers BC are arranged in this direction.

A readout gate ROG is disposed between each V register BC and the corresponding photosensitive unit 11. Furthermore, a channel stop CS is provided at the boundary of each unit cell.

The bottom end of each V register BC adjoins a line H register (a horizontal a CCD or horizontal transmission segment) that extends in the horizontal direction in the drawing. At a downstream end (the left in the drawing) of the H register is coupled to a charge detector 19 having, for example, a floating diffusion amplifier configuration. The charge detector 19 sequentially converts the signal charges input from the H register into signal voltages as CCD outputs.

A readout pulse XSG from a timing generator TG is applied to the gate electrode of a readout gate ROG to increase the potential depth under the gate electrode, so that the corresponding V register BC reads out the signal charge accumulated in each photosensitive unit 11 through the readout gate ROG.

The V register BC is driven by four-phase vertical transmission pulses φV1 to φV4 having different phases that correspond to the vertical transmission electrodes V1 to V4 by a progressive scan mode (non-interlace mode). The signal charge read out from each photosensitive unit 11 is transmitted in the vertical direction for every scanning line (one line) at a part of a horizontal blanking time to the H register. The V register BC may be driven by a three-phase mode in place of the four-phase mode.

The H register horizontally transmits the signal charges corresponding to one line that are vertically transmitted from the respective V registers BC, based on two-phase horizontal transmission pulses φH1 and φH2 that are generated in the timing generator TG.

The charge detector 19 accumulates the signal charges sequentially injected from the H register into a floating diffusion (not shown), and the accumulated signal charges are converted into signal voltages that are output as CCD output signals through, for example, an output circuit (not shown) with a source follower structure.

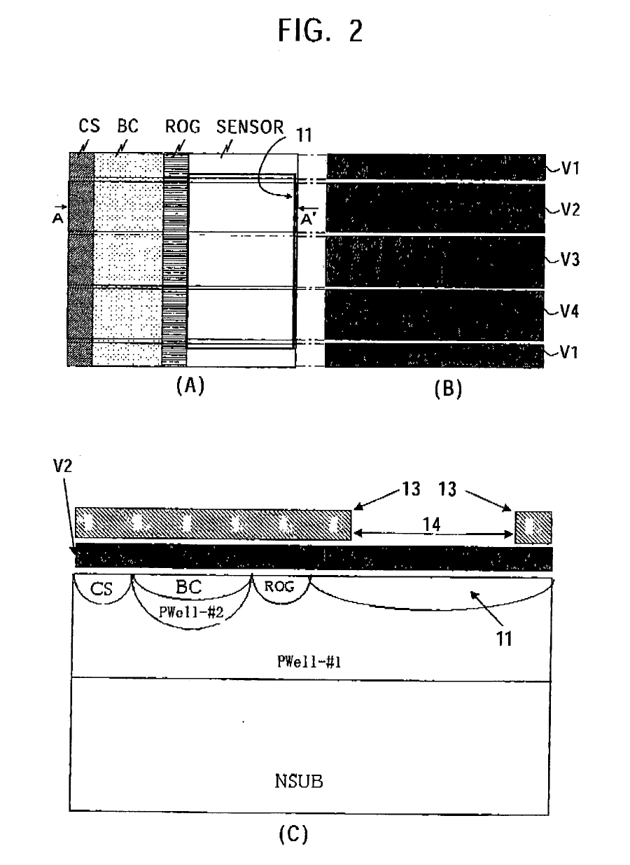

FIGS. 2(A), 2(B), and 2(C) show full details about vertical transmission electrodes of a unit cell in the solid-state image-sensing device 10 shown in FIG. 1 (hereinafter referred to as a first embodiment). FIG. 2(A) shows a planar structure of the unit cell, FIG. 2(B) shows a planar pattern of an electrode structure of the V register BC, and FIG. 2(C) is an enlarged cross-sectional view taken along line A-A′ in FIG. 2(A).

Referring to FIG. 2(C), the unit cell includes a semiconductor substrate NSUB composed of, for example, silicon, a PWell-#1 formed on the semiconductor substrate NSUB. A photosensitive unit (sensor) 11 composed of a photodiode, a readout gate ROG, a V register BC with a PWell-#2, and a channel stop CS are formed on the PWell-#1 from the left in the horizontal direction in the drawing.

Above these layers, a gate insulating film (not shown) is provided, and vertical transmission electrodes V1 to V4 for the V register BC are arranged on the gate insulating film. Furthermore, an insulating interlayer (not shown) is provided on these electrodes, and a shading film 13 is formed above the photosensitive unit 11 so as to form a sensor opening 14. Four-phase drive pulses having different phases are supplied to the vertical transmission electrodes V1 to V4 so that the unit cell functions as a progressive scan CCD image sensor.

The shading film 13 that entirely covers the solid-state image-sensing device 10 has the opening 14 above the photosensitive unit 11 that is shown by a thick frame in FIG. 2(A) (the opening 14 is not depicted in FIG. 2(A)). Light is incident on the photosensitive unit 11 through the opening 14.

The solid-state image-sensing device according to the first embodiment has the same underlying structure as that of a conventional IT-CCD. However, rectangular overlying electrodes horizontally extend above the photosensitive unit 11, irrespective of vertical pixel arrangement. In other words, the electrode structure for vertical transmission is a single-layer structure including the four-phase vertical transmission electrodes V1 to V4 extending in the same plane above the photosensitive unit 11.

In this embodiment, vertical transmission electrodes V1 to V4 are formed of a transparent film. Examples of materials for the transparent film include thin-film polycrystalline silicon with a transparency thickness of 100 nm or less, and transparent conductive substances such as In₂O₃-based materials, i.e., indium tin oxide (ITO), and ZnO-based materials. The vertical transmission electrodes V1 to V4 may have a multilayer structure including a polycrystalline silicon thin film and a transparent conductive thin film of ITO or ZnO. This multilayer structure functions as a single layer electrode because these films function as a single electrode.

In the solid-state image-sensing device 10 in the first embodiment, the vertical transmission electrodes V1 to V4 for four-phase drive have a single-layer structure; hence, these electrodes V1 to V4 substantially do not generate overlap capacitance, resulting in reduced power consumption in the V registers.

Since the vertical transmission electrodes V1 to V4 horizontally extending above the photosensitive unit 11 are formed of transparent films, the photosensitive unit 11 can receive incident light with high intensity and thus have high sensitivity to the incident light.

Furthermore, the single-layer structure of the vertical transmission electrodes V1 to V4 results in a reduced aspect ratio at a portion above the unit cell. Such a low aspect ratio enables a reduction in size of the unit cell of the progressive scan CCD, and an improvement in sensitivity at a large F value.

Furthermore, the vertical transmission electrodes V1 to V4 can be formed of the same material, i.e., polycrystalline silicon or ITO, in one production process, resulting in low production cost.

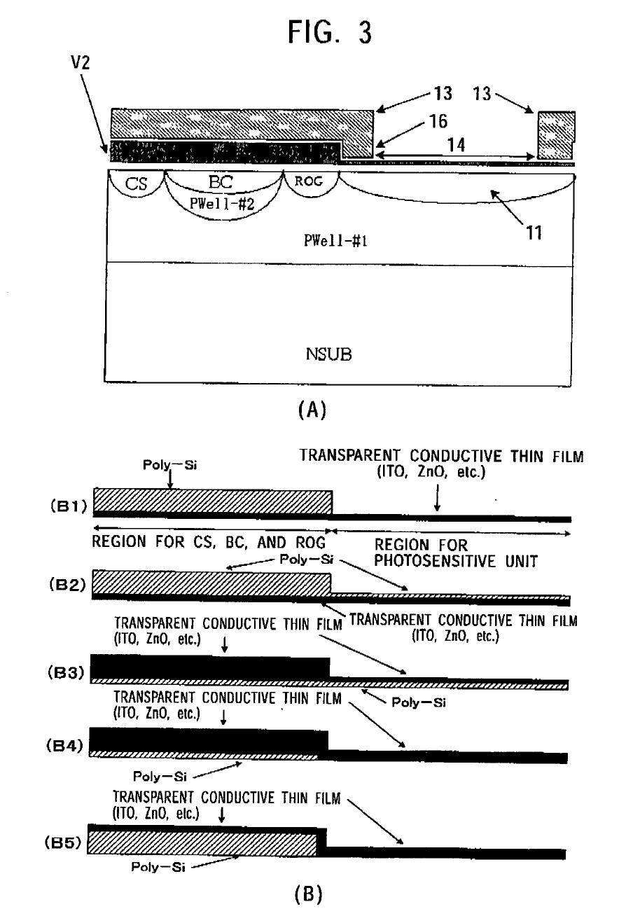

FIGS. 3(A) and 3B show vertical transmission electrodes of the solid-state image-sensing device 10 shown in FIG. 1 (hereinafter referred to as a second embodiment). FIG. 3(A) is an enlarged cross-sectional view taken along line A-A′ in FIG. 2(A), and FIG. 3B shows examples of multilayer structures of the vertical transmission electrodes V1 to V4.

Each of the vertical transmission electrodes V1 to V4 in the second embodiment is composed of a thin electrode segment and a thick electrode segment. The thick electrode segment is disposed above the photosensitive unit 11 whereas the thick electrode segment is disposed over the readout gate ROG, the V register BC, and the channel stop CS. In summary, the thickness of these electrodes V1 to V4 is thinner above the photosensitive unit 11 than above other portions. For example, the thin electrode segment is composed of polycrystalline silicon with a transparent thickness of 100 nm or less.

The shading film 13 has a downward projection 16 at the edge of the opining 13 at the boundary between the thin electrode segment and the thick electrode segment. The shading film 13 blocks light reflected diffusely, reducing light leakage toward the V register BC,

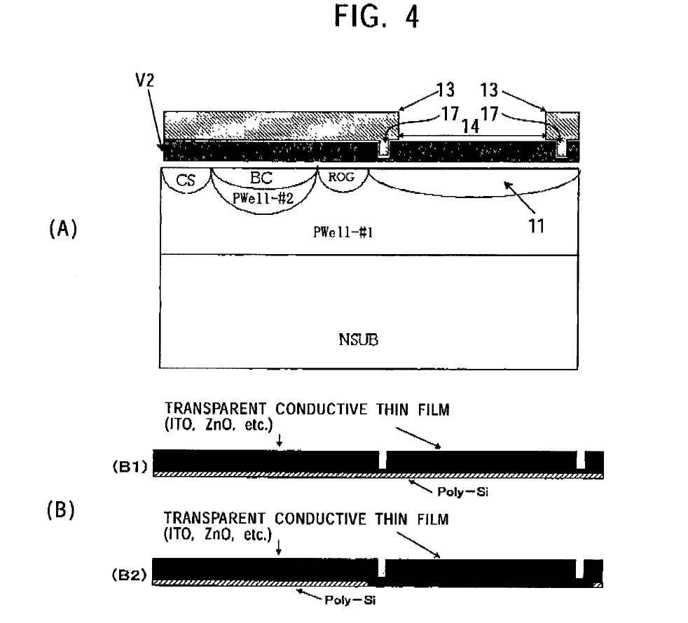

In this embodiment, the shading film 13 has an L cross-section at an edge of the opening 14 to form the projection 16. The projection 16 may have any shape other than that shown in FIG. 3. For example, as shown in FIG. 4(A), projection 16 may be slightly moved from the edge of the opening 14 toward the V register BC. If the thickness of the vertical transmission electrodes are larger between pixels lying in the vertical direction are larger than above the photosensitive unit 11, the projection 16 may also extend between these pixels.

In the second embodiment, the thickness of the vertical transmission electrodes V1 to V4 is smaller above the photosensitive unit 11 than above other portions, This structure can suppress a decrease in sheet resistance of the electrodes and a decrease in transmittance incident light due to thinning. Thus, the structure in the second embodiment exhibits higher sensitivity than that of the first embodiment.

Furthermore, the downward projection 16 provided to the shading film 13 more effectively prevents leakage of the incident light toward the V register BC compared with the first embodiment. Thus, this structure can suppress generation of a smear component as much as possible in the IT-CCD.

The thin electrode segment and the thick electrode segment of each of the vertical transmission electrodes V1 to V4 may be formed as follows using the same material. A first mask dedicated for the thick electrode segment and a second mask dedicated for both the thin electrode segment and the thick electrode segment are prepared. Electrode layers with a thickness of the thick electrode segment are formed, and etched through the first mask. Next, electrode layers with a thickness of the thin electrode segment are formed, and etched through the second mask. Alternatively, electrode layers with a thickness of the thick electrode segment are formed and are etched through the second mask. Alternatively, electrode layers with a thickness of the thin electrode segment are formed and etched through the second mask, and then the thin electrode segment is etched through the first mask. In the last case, the end point of the etching is not detected. Thus, the thickness of the thin electrode segment may be controlled with an etching time calculated from the etching rate.

The thin electrode segment and the thick electrode segment may have a single-layer structure composed of a transparent conductive material such as ITO or thin polycrystalline silicon with a thickness of 100 nm or less. Alternatively, as shown in FIGS. 3(B1) to 3(B5), these segments may have a multilayer structure.

For example, in FIG. 3(B1), a transparent conductive film of ITO or ZnO is formed on the entire surface in the horizontal direction in the drawing, and then a polycrystalline silicon film is formed on the transparent conductive film other than above the photosensitive unit 11. In this structure, the polycrystalline silicon is formed on the entire surface of the transparent conductive film and is etched above the photosensitive unit 11 through a mask. Since the transparent conductive film functions as an etching stopper, the electrodes having a desired profile can be readily formed.

In the structure shown in FIG. 3(B1), when the underlying transparent conductive thin film does not function as an etching stopper, the polycrystalline silicon film with a small thickness may be partly left above the photosensitive unit 11.

This double-layer structure above the photosensitive unit 11 poorly compares with a single-layer structure in sensitivity of the photosensitive unit 11. However, the polycrystalline silicon film can be more readily processed compared with the transparent conductive thin film. Thus, this double-layer structure facilitates the formation of the vertical transmission electrodes V1 to V4, compared with the single-layer structure of a transparent conductive thin film.

In the structure shown in FIG. 3(B3), a thin polycrystalline silicon film is formed on the entire surface in the horizontal direction, and a transparent conductive thin film is formed on the polycrystalline silicon film. The thickness of the transparent conductive thin film is smaller above the photosensitive unit 11 than above the readout gate ROG, the V register BC, and the channel stop CS. In conclusion, the vertical transmission electrodes have a double layer structure of the polycrystalline silicon film and the transparent conductive thin film having different thicknesses between the photosensitive unit 11 and the other portions.

Since the vertical transmission electrodes have a double-layer structure above the photosensitive unit 11, the light transmittance of the electrodes is lower than that of a single-layer structure. However, the bottom layer of the vertical transmission electrode above the readout gate ROG, the V register BC, and the channel stop CS enables the Vth of a MOS capacitor constituting the V register BC to be equal to the Vth of conventional polycrystalline silicon.

In addition, the upper transparent conductive film suppresses an increase in surface potential of the MOS capacitor, and thus suppresses an increase in dark current in the v register BC.

In the structure shown in FIG. 3(B4), a double-layer structure is employed only above the readout gate ROG, the V register BC, and the channel stop CS, whereas a single-layer structure is employed above the photosensitive unit 11. In the double-layer structure, the bottom layer is composed of polycrystalline silicon.

Since a single-layer structure is employed above the photosensitive unit 11, high light transmittance is achieved above the photosensitive unit 11. Furthermore, the bottom layer above the readout gate ROG, the V register BC, and the channel stop CS enables the Vth of a MOS capacitor constituting the V register BC to be equal to the Vth of conventional polycrystalline silicon. In addition, the upper transparent conductive film suppresses an increase in surface potential of the MOS capacitor, and thus suppresses an increase in dark current in the V register BC.

In the structure shown in FIG. 3(B5), a polycrystalline silicon film is formed only above the readout gate ROG, the V register BC, and the channel stop CS, and then a transparent conductive thin film with a uniform thickness is formed over the entire surface including the photosensitive unit 11.

This structure has substantially the same advantages as those in the structure shown in FIG. 3(B4). Furthermore, the transparent conductive thin film has the same thickness over the entire region; hence, the vertical transmission electrodes can be more readily formed compared with the structure shown in FIG. 3(B4).

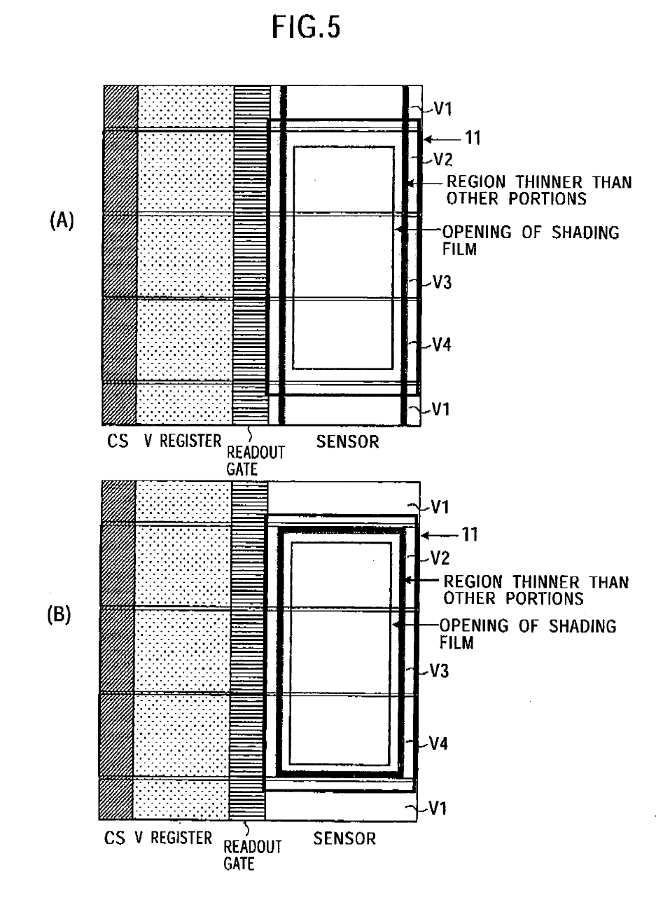

FIGS. 4(A) and 4B show a fourth embodiment of the vertical transmission electrodes V1 to V4 of the solid-state image-sensing device 10; FIG. 4(A) is an enlarged cross-sectional view taken along line A-A′ in FIG. 2(A), and FIG. 4B shows examples of multilayer structures of the vertical transmission electrodes V1 to V4. FIGS. 5(A) and 5(B) are plan views of unit cells in which the vertical transmission electrodes V1 to V4 are thinner than in other portions.

In the structure shown in FIG. 5(A) according to the third embodiment, the vertical transmission electrodes V1 to V4 are thinner above limited regions of the photosensitive unit 11 than above other regions. More specifically, the electrodes above the photosensitive unit 11 are thinner only in regions that extend in the vertical direction near both vertical edges of the photosensitive unit 11. Herein, the vertical edges are disposed in the transverse direction in the drawing.

In the structure shown in FIG. 5(B) according to the third embodiment, the vertical transmission electrodes V1 to V4 are also thinner above limited regions of the photosensitive unit 11 than above other regions. More specifically, the electrodes above the photosensitive unit 11 are thinner only in regions near four edges of the photosensitive unit 11,

In the structure shown in FIG. 5(A), as shown in FIG. 4(A), the shading film 13 has projections 17 above the photosensitive unit 11, the projections 17 vertically extending near both vertical edges of the photosensitive unit 11. These projections 17 correspond to the thinner portions of the vertical transmission electrodes V1 to V4, In the structure shown in FIG. 5(B), as shown in FIG. 4(A), the shading film 13 has projections 17 above the photosensitive unit 11, the projections 17 extending near four edges of the photosensitive unit 11. These projections 17 correspond to the thinner portions of the vertical transmission electrodes V1 to V4. Since the projections 17 block the diffused reflection light as in the second embodiment, light does not enter the V register BC.

In FIG. 4, the projections 17 are disposed portions that are slightly indented from the edges of the opening 14 near the both edges of the photosensitive unit 11. The shape of the projections 17 is not limited to this structure. For example, as in the second embodiment shown in FIG. 3(A), the electrode material may have an L shape at least at an edge of the opening 14.

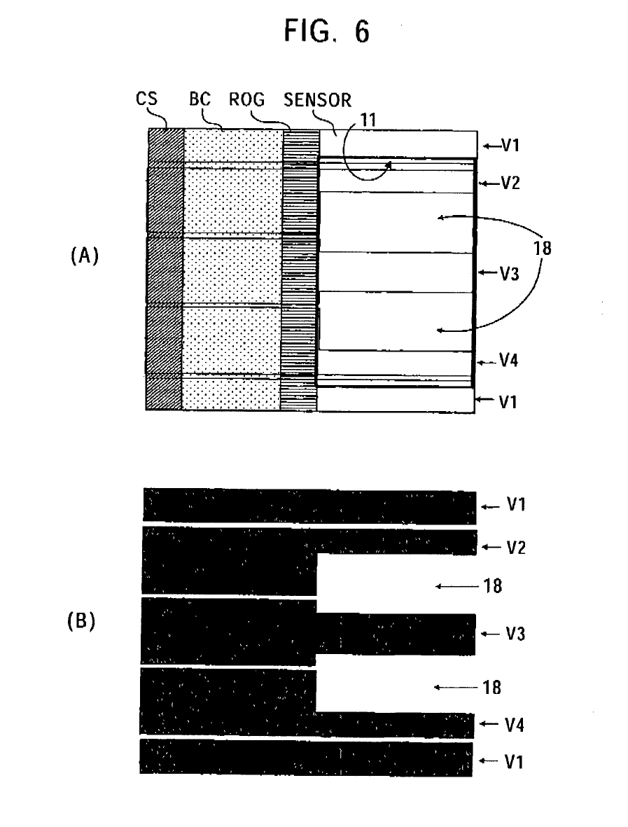

In the third embodiment shown in FIGS. 5(A) and 6(B), the thickness of the vertical transmission electrodes V1 to V4 above the photosensitive unit 11 is larger than that in the second embodiment. Thus, the vertical transmission electrodes V1 to V4 in the third embodiment has smaller light transmittance than those in the second embodiment. However, the structure of the third embodiment does not cause an increase in sheet resistance of the electrodes. Accordingly, this structure is suitable for high-rate signal transmission compared with that in the second embodiment, Furthermore, the projections 17 of the shading film 13 further ensure blocking of the leakage of light toward the V register BC compared with the first embodiment. Thus, this structure can suppress generation of a smear component as much as possible in the IT-CCD.

The local thinner portions of the vertical transmission electrodes V1 to V4 may be formed as follows: A first mask dedicated for only a thicker portion and a second mask dedicated for both the thicker portion and a thinner portion are prepared. First, thicker electrode layers are formed and are etched through the first mask. Next, thinner electrode layers are formed and are etched through the second mask. Alternatively, thick electrodes layers are formed and are etched through the second mask, and then thinner portions are etched by a predetermined thickness through the first mask. In the latter case, the end point of the etching is not detected. Thus, the thickness of the thin electrode segment may be controlled with an etching time calculated from the etching rate.

The thinner portions of the vertical transmission electrodes V1 to V4 vertically extending near both vertical edges of the photosensitive unit 11 or lying near four edges of the photosensitive unit 11 may have a single-layer structure composed of a transparent conductive layer or a thin polycrystalline silicon layer with a thickness of 100 nm or less, or may have a multilayer structure as shown in FIGS. 4(B1) and 4(B2).

For example, in a structure shown in FIG. 4(B1), a thin polycrystalline silicon layer is formed on the entire region in the horizontal direction and a transparent conductive material layer is formed thereon such that predetermined regions vertically extending near both vertical edges of the photosensitive unit 11 are thinner than other portions, or predetermined regions within the photosensitive unit 11 along four edges of the photosensitive unit 11 are thinner than other portions. Thus, the structure shown in FIG. 4(B1) is a double-layer structure of the polycrystalline silicon layer and the transparent conductive layer that is locally thinned.

Although this double-layer structure disadvantageously exhibits relatively low transmittance of light incident on the photosensitive unit 11, the lower polycrystalline silicon layer above the v register BC enables the Vth of a MOS capacitor constituting the V register BC to be equal to the Vth of conventional polycrystalline silicon. In addition, the upper transparent conductive film suppresses an increase in surface potential of the MOS capacitor, and thus suppresses an increase in dark current in the V register BC. Furthermore, only the above-described limited regions of the vertical transmission electrodes V1 to V4 are thinned; hence, the sheet resistance of these electrodes does not substantially increase, resulting in higher signal transmittance.

In a structure shown in FIG. 4(B2), a thin polycrystalline silicon layer is formed only on the readout gate ROG, the V register BC, and the channel stop CS and a transparent conductive material layer is formed over the entire area such that predetermined regions vertically extending near both vertical edges of the photosensitive unit 11 are thinner than other portions, or predetermined regions within the photosensitive unit 11 along edges of the photosensitive unit 11 are thinner than other portions.

This structure ensures high transmittance of light incident on the photosensitive unit 11 because of a single-layer structure above the photosensitive unit 11, Furthermore, the lower polycrystalline silicon layer above the V register BC enables the Vth of a MOS capacitor constituting the V register BC to be equal to the Vth of conventional polycrystalline silicon. In addition, the upper transparent conductive film suppresses an increase in surface potential of the MOS capacitor, and thus suppresses an increase in dark current in the V register BC. Furthermore, only the above-described limited regions of the vertical transmission electrodes V1 to V4 are thinned; hence, the sheet resistance of these electrodes does not substantially increase, resulting in higher signal transmittance.

FIG. 6(A) is a plan view of the unit cell of the solid-state image-sensing device 10 shown in FIG. 1, and FIG. 6(B) is a schematic view showing a planar pattern of the vertical transmission electrodes for the V register BC, according to a fourth embodiment of the present invention.

Since polycrystalline silicon has low transmittance at a blue or shorter-wave light region, vertical transmission electrodes V1 to V4 composed of polycrystalline silicon exhibit low sensitivity to blue light. In the fourth embodiment, the vertical transmission electrodes V1 to V4 have windows 18 at limited regions above the photosensitive unit 11 to improve the sensitivity to blue light.

In the first to third embodiments, gaps between the vertical transmission electrodes V1 to V4 arranged in parallel function as windows that transmit blue light. However, the total area of the windows (aperture ratio) is not sufficient for ensuring sensitivity to blue light. Thinning of the electrodes on the photosensitive unit 11 in the second embodiment still has a relative decrease in sensitivity to blue light compared with other longer-wavelength light such as green and red, irrespective of an improvement in total light transmittance.

In contrast, in the fourth embodiment, the windows 18 provided in the vertical transmission electrodes V1 to V4 facilitate direct incidence of light containing a blue component on the photosensitive unit 11. Thus, the sensitivity of the photosensitive unit 11 to blue light is improved compared with the structures shown in the first to third embodiments.

The technical scope of the present invention is not limited to the above embodiments and may include various modifications and improvements. The above embodiments do not limit the scope of the present invention and all the combinations described in the preferred embodiments are not always necessary for the present invention.

For example, in the above embodiments, all the vertical transmission electrodes on the photosensitive unit are composed of a transparent substance or transparent substances. However, there is no need to form all the vertical transmission electrodes with a transparent substance. Among these vertical transmission electrodes, at last one electrode is transparent and is provided on the photosensitive unit.

In the above embodiments, the transparent conductive materials are In₂O₃-based materials such as ITO and ZnO-based materials. Any other transparent conductive materials may also be used in the present invention. For example, for solid-state image-sensing devices for detecting visible light, the transparent conductive materials may be SnO₂-based materials and Cd₂SnO₄ that exhibit high transmittance (about 85 to 90% or more) to visible light,

What is claimed is:

1. A solid-state image-sensing device comprising a two-dimensional array of a plurality of photosensitive units and a plurality of vertical CCD segments, each vertical CCD segment being provided for one vertical line of the photosensitive units, a plurality of vertical transmission electrodes extending above each of the plurality of vertical transmission electrodes,
wherein at least one of the vertical transmission electrodes is arranged above the photosensitive units and is composed of a transparent film at least in regions above the photosensitive units.

2. The solid-state image-sensing device according to claim 1, wherein at least two of the plurality of vertical transmission electrodes are composed of the transparent film and are arranged with a predetermined gap in the same plane.

3. The solid-state image-sensing device according to claim 1, wherein the transparent film is a transparent conductive thin film composed of indium tin oxide or zinc oxide.

4. The solid-state image-sensing device according to claim 1, wherein the transparent film is a polycrystalline silicon thin film having light transparency.

5. The solid-state image-sensing device according to claim 1, wherein at least a part of the transparent film is a composite film of a transparent conductive layer and a polycrystalline silicon thin layer having light transparency.

6. The solid-state image-sensing device according to claim 1, wherein the vertical transmission electrodes have windows above parts of the photosensitive units so that light is directly incident above the photosensitive units.

7. The solid-state image-sensing device according to claim 1, wherein the thickness of the vertical transmission electrodes is smaller above the photosensitive units than above the vertical CCD units.

8. The solid-state image-sensing device according to claim 1, wherein the thickness of the vertical transmission electrodes above each of the photosensitive units is smaller in regions vertically extending near vertical edges of the photosensitive unit than in other portions.

9. The solid-state image-sensing device according to claim 1, wherein the thickness of the vertical transmission electrodes above each of the photosensitive units is smaller in regions near edges of the photosensitive unit than in other portions.

10. The solid-state image-sensing device according to claim 1, further comprising a shading film over the vertical transmission electrodes, the shading film having windows above the photosensitive units so that light is directly incident on the photosensitive units, the shading film having projections that vertically extend at vertical edges of each of the photosensitive units.

11. The solid-state image-sensing device according to claim 1, further comprising a shading film over the vertical transmission electrodes, the shading film having windows above the photosensitive units so that light is directly incident on the photosensitive units, the shading film having projections at edges of each of the photosensitive units.
